(19) United States
(12) Patent Application Publication
(10) Pub. No.: US 2023/0056755 A1
(43) Pub. Date: Feb. 23, 2023

(54) Semiconductor package

(71) Applicant: Tienchien Cheng, HSIN CHU CITY (TW)

(72) Inventor: Tienchien Cheng, HSIN CHU CITY (TW)

(21) Appl. No.: 17/891,886

(22) Filed: Aug. 19, 2022

Related U.S. Application Data
(60) Provisional application No. 63/235,282, filed on Aug. 20, 2021.

(51) Int. Cl. H01L 23/66; H01L 25/16; H01L 23/00; H01Q 1/22; H01Q 1/38; H01L 23/498

(52) U.S. Cl. CPC H01L 23/66; H01L 25/162; H01L 24/08; H01L 24/16; H01L 24/13; H01Q 1/2283; H01Q 1/38; H01L 23/49816; H01L 23/49833; H01L 23/49838; H01L 24/05; H01L 2924/1436; H01L 2924/1437; H01L 2924/1444; H01L 2924/19041; H01L 2924/19042; H01L 2924/19043; H01L 2224/13147; H01L 2223/6616; H01L 2223/6672; H01L 2223/6677; H01L 2924/2027; H01L 2924/182; H01L 2924/186; H01L 2224/08121; H01L 2224/08225; H01L 2924/1432; H01L 2924/1421; H01L 2224/16225; H01L 2224/05647

(57) ABSTRACT

A semiconductor package includes a substrate, an interposer, a primary component layer, a first redistribution layer, multiple solder bumps and a first hybrid bonding structure. The interposer is disposed above the substrate and includes multiple TSV sets. The primary component layer is disposed above the interposer and includes multiple first chips and a first molding material that fills the space between the multiple first chips. The first redistribution layer is disposed between the primary component layer and the interposer and includes at least one portion of an antenna structure. The plurality of solder bumps is disposed between the substrate and the interposer. The first hybrid bonding structure is disposed between the multiple first chips and the multiple TSV sets for electrical connection in between and includes multiple connection components that respectively apply bonding of multiple metal pieces in between.

### CROSS REFERENCE TO RELATED APPLICATION

This application claims the benefit of U.S. Provisional Application No. 63/235,282, filed on Aug. 20, 2021 and entitled “Semiconductor package with cooling structure and antenna module”, the contents of which are incorporated herein by reference.

### BACKGROUND OF THE INVENTION

### 1. Field of the Invention

The present invention relates to a semiconductor package, and more particularly, to a semiconductor package having improved package density for fitting components.

### 2. Description of the Prior Art

A conventional semiconductor package is easily limited in its package capability and has low level of component integration. Therefore, there is always a drive to raise a semiconductor package's capability and level of component integration.

### SUMMARY OF THE INVENTION

The present disclosure aims at disclosing a semiconductor package.

In a first example, the semiconductor package includes a substrate, an interposer, a primary component layer, a first redistribution layer, a plurality of solder bumps and a first hybrid bonding structure. The interposer is disposed above the substrate. Also, the interposer comprises a plurality of through silicon vias (TSV) sets. The primary component layer is disposed above the interposer. And the primary component layer includes a plurality of first chips and a first molding material. The first molding material is utilized for filling the space between the plurality of first chips. The first redistribution layer is disposed between the primary component layer and the interposer. Moreover, the first redistribution layer includes at least one portion of an antenna structure. The plurality of solder bumps is disposed between the substrate and the interposer. The first hybrid bonding structure is disposed between the plurality of first chips and the plurality of TSV sets for electrical connection in between. In addition, the first hybrid bonding structure includes a plurality of connection components that respectively apply bonding of a plurality of metal pieces in between.

In one example, each of the plurality of connection components applies bonding of a plurality of aligned metal pieces in between.

In one example, each of the plurality of connection components applies bonding of a plurality of shifted metal pieces in between.

In one example, the semiconductor package also includes a second redistribution layer that is disposed between the interposer and the plurality of solder bumps.

In one example, the semiconductor package also includes a flip chip bump that is formed as a connection between the interposer and the substrate.

In one example, the interposer further includes at least one second chip that is disposed between two of the plurality of TSV sets.

In one example, the interposer is silicon-based.

In one example, the interposer also includes at least one passive component. Besides, the first molding material fills the space between the plurality of first chips and the at least one passive component.

In one example, the semiconductor package additionally includes an under-fill material that fills space between the plurality of the solder bumps.

In one example, the substrate includes at least one passive component.

In one example, each of the plurality of connection components includes a plurality of copper pillars.

In one example, the semiconductor package also includes at least one bridge to part or all of the plurality of TSV sets.

In one example, the at least one bridge has same or different levels, or a combination of same and different levels.

In one example, the semiconductor package additionally includes a supplemental layer and a second hybrid bonding structure. The supplemental layer includes a plurality of third chips and a second molding material that fills the space between the plurality of third chips. The second hybrid bonding structure establishes connection between the plurality of first chips and the plurality of third chips. Besides, the second hybrid bonding structure includes a plurality of connection components that respectively apply bonding of a plurality of metal pieces in between.

In one example, the supplemental layer also includes a plurality of through glass vias (TGV) sets. At least one of the plurality of third chips are disposed in two of the plurality of TGV sets.

In one example, the supplemental layer also includes a plurality of through mold vias (TMV) sets. At least one of the plurality of third chips are disposed in two of the plurality of TMV sets.

In one example, the supplemental layer also includes at least one passive component. In addition, the second molding material fills the space between the plurality of third chips and the at least one passive component.

In one example, the primary component layer additionally includes a plurality of connection via structures that are respectively disposed on top of the plurality of first chips and are connected to the plurality of first chips.

In one example, each of the plurality of connection via structures includes a copper via, a metal pad, a first polyimide layer, a second polyimide layer, an extended via, a first lateral pad and a second lateral pad. The metal pad is disposed below the copper via. The first polyimide layer is disposed below the metal pad. The second polyimide layer is disposed below the first polyimide layer. The extended via goes through the first polyimide layer and the second polyimide layer. The first lateral pad is formed near a lower surface of the second polyimide layer. The second lateral pad is formed on an end of the extended via.

In one example, each of the plurality of connection via structures includes a copper via, a metal pad, a first polyimide layer, a second polyimide layer, an extended via, a first lateral pad and a second lateral pad. The metal pad is disposed below the copper via. The first polyimide layer is disposed below the metal pad. The second polyimide layer is disposed below the first polyimide layer. The extended via goes through the first polyimide layer and the second polyimide layer. The first lateral pad is disposed between the first polyimide layer and the second polyimide layer. The second lateral pad is formed near the lower surface of the second polyimide layer.

In a second example, the semiconductor package includes a molded layer, a first redistribution layer, a substrate and a plurality of solder bumps. The molded layer's top has a portion of an antenna structure. In addition, the molded layer includes a plurality of chips and a molding material that fills the gap between the plurality of chips. The first redistribution layer is disposed neighboring to the molded layer. And the first redistribution layer is a grounding layer for the antenna structure. The plurality of solder bumps are disposed between the substrate and the interposer. Besides, the substrate connects to the molded layer through the plurality of solder bumps.

In one example, the semiconductor package additionally includes a connector that is connected to the substrate through the plurality of solder bumps.

In one example, the semiconductor package also includes a plurality of vias that are disposed on top of the plurality of chips. Moreover, the plurality of vias provide spacing of the antenna structure.

In one example, the plurality of vias includes copper vias.

In one example, the molded layer also includes at least one passive element and a plurality of through mold vias (TMV). The molding material additionally fills the gap between the plurality of chips, the at least one passive element and the plurality of TMVs.

These and other objectives of the present invention will no doubt become obvious to those or ordinary skill in the art after reading the following detailed description of the preferred embodiment that is illustrated in the various figures and drawings.

### BRIEF DESCRIPTION OF THE DRAWINGS

FIG. 1 illustrates a semiconductor package according to a first embodiment of the present disclosure.

FIG. 2 illustrates several alternative examples of hybrid bonding structures and TSVs of the semiconductor package shown in FIG. 1 according to some examples of the present disclosure.

FIG. 3 shows a cross-sectional view and a top view of the interposer shown in FIG. 1.

FIG. 4 shows a top view of the semiconductor package shown in FIG. 1 according to one example.

FIGS. 5-6 show the semiconductor package shown in FIG. 1 according to one example.

FIG. 7 shows a top view of the semiconductor package shown in FIG. 1 according to one example.

FIG. 8 shows a semiconductor package according to a second embodiment of the present disclosure.

FIGS. 9-10 show the semiconductor package shown in FIG. 8 according to one example.

FIGS. 11-12 show the semiconductor package shown in FIG. 1 according to one example.

FIG. 13 shows a semiconductor package according to one example.

FIGS. 14-15 show a semiconductor package that includes a first layer and a second layer according to one example.

FIG. 16 shows a semiconductor package according to a third embodiment of the present disclosure.

FIGS. 17-19 show a semiconductor package according to one example that shares certain resemblance with FIG. 16.

FIGS. 20-22 show a top view of the semiconductor package shown in FIG. 16 according to one example.

FIG. 23 shows a semiconductor package according to a fourth embodiment of the present disclosure.

FIG. 24 shows a cross-sectional view and a top view of the interposer of the semiconductor package shown in FIG. 23.

FIG. 25 shows a top view of the semiconductor package shown in FIG. 23 according to one example that shares certain resemblance to that of FIG. 4.

FIGS. 26-27 show a semiconductor package according to one example that is similar with the semiconductor package shown in FIG. 8.

FIG. 28 shows a semiconductor package according to one example that is similar with the semiconductor package shown in FIG. 14.

FIG. 29 shows top views of different types of antenna modules that are optionally applied in the above-disclosed semiconductor packages according to some examples of the present disclosure.

FIG. 30 shows a cross-sectional view of an antenna module that is optionally applied in the above-disclosed semiconductor packages according to some examples of the present disclosure.

### DETAILED DESCRIPTION

As mentioned above, the present disclosure discloses a semiconductor package of raised package capability. Specifically, the semiconductor package disclosed in the present disclosure includes two primary features: interposer and multi-band molded module.

### Interposer

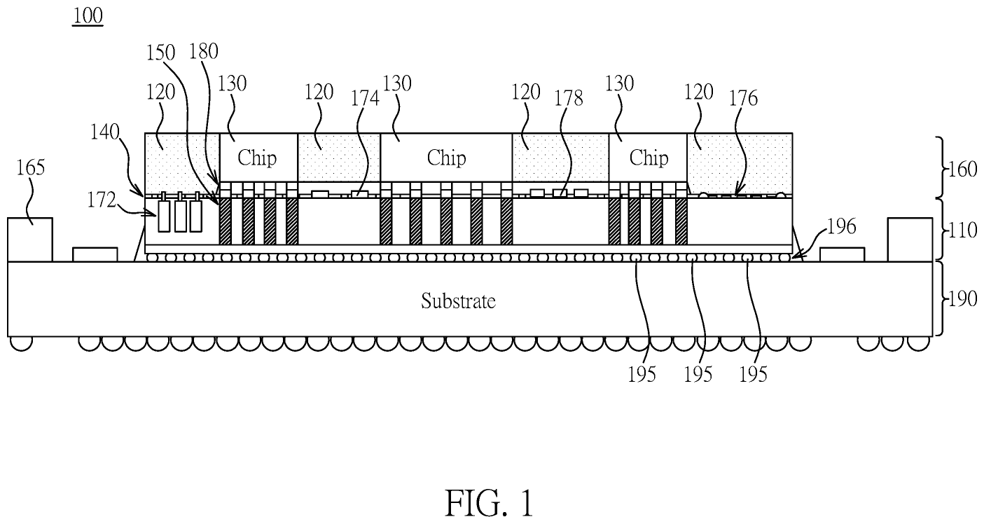

FIG. 1 shows a semiconductor package 100 according to a first embodiment of the present disclosure. The semiconductor package 100 includes at least a memory module in an interposer 110. The interposer 110 may include any one type of the following memory modules, for example, DRAM. SRAM, or RRRAM. The interposer 110 is located below an upper layer 160 (i.e., a primary component layer) that may include at least one chip 130. At least one molding material 120 can be used to fill the space between the chips 130 in the upper layer 160. The interposer 110 may be silicon-based. The interposer 110 may include multiple TSV sets 150 (through silicon via). The interposer 110 may include components, such as capacitors 172, inductors 174, and/or resistors 176. The semiconductor package 100 may include a RDL (redistribution layer) structure 140 between the upper layer 160 and the interposer 110. The RDL structure 140 may include at least one portion of an antenna structure.

The semiconductor package 100 may further includes a substrate 190, which may be implemented by a printed circuit board (PCB), an ABF (Ajinomoto Build-up Film) substrate, or a BT (Bismaleimide Triazine) substrate. Multiple solder bumps 195 can be located between the substrate 190 and the interposer 110. An under-fill material 196 may be used to fill the space between the solder bumps 195. Components such as capacitors, inductors, or resistors can be added onto the substrate 190. A hybrid bonding structure 180 and the TSV SETs 150 for electrical connection in between. The hybrid bonding structure 180 may include multiple connection components, each of which applies bonding of two metal pieces in between, such as two or more copper pillars. With the aid of the hybrid bonding structure 180, the semiconductor package 100 can have 10 μm pitches or less then 10 μm pitches. Consequently, the semiconductor package 100 has better signal integrity and data bandwidth via the hybrid bonding structure 180.

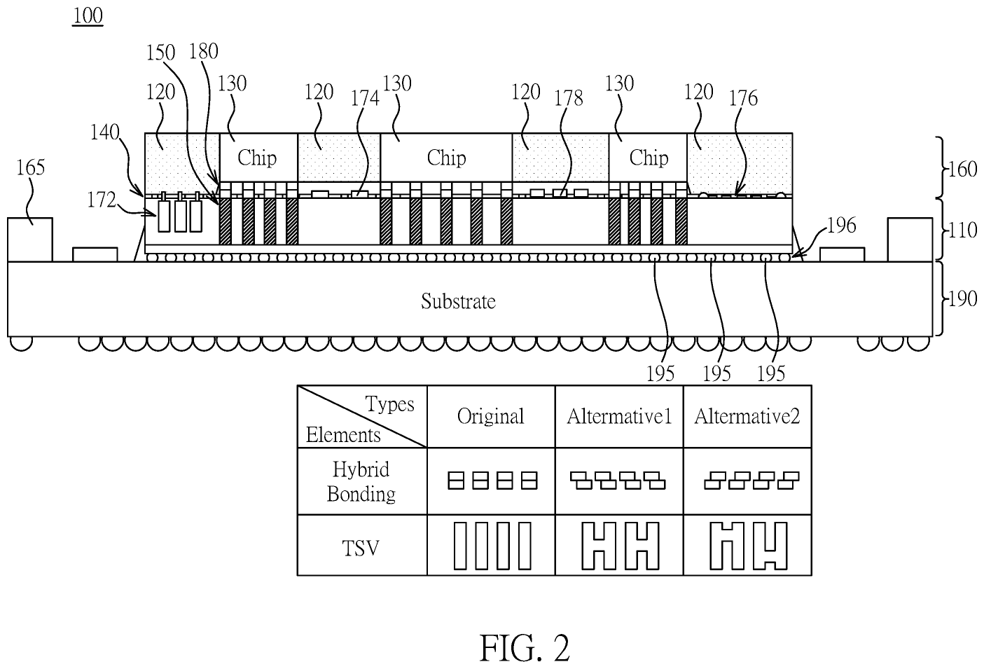

FIG. 2 illustrates several alternative examples of hybrid bonding structures 180 and TSV SETs 150 of the semiconductor package 100 according to some examples of the present disclosure. In a first example, an original type of the original bonding structure 180 includes connection components with bonding of two aligned metal pieces. In a second example, an alternative type of hybrid bonding structure 180 includes connection components with bonding of two shifted metal pieces. Specifically, the two metal pieces are slightly shifted but still have effective physical connection in between. The shifts can be arranged as a left-to-right tilt, i.e., Alternative 1 shown in FIG. 2, or as a right-to-left tilt, i.e., Alternative 2 shown in FIG. 2. With the aid of the shifted metal pieces, the semiconductor package 100 of the present disclosure can allow better error tolerance in fabrication.

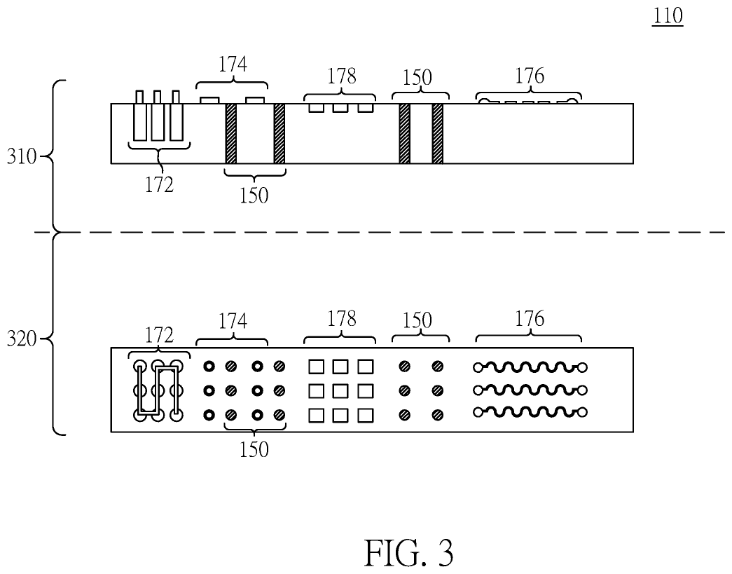

FIG. 3 shows a cross-sectional view 310 and a top view 320 of the interposer 110 shown in FIG. 1. The cross-sectional view 310 shows capacitors 172, the TSV SETs 150, and memory cells 178 in the interposer 110. The cross-sectional view 310 also shows the inductors 174 and the resistors 176 on one surface of the interposer 110. The top-view 320 shows the top ends of the capacitors 172, the front face of the inductors 174, the top ends of the TSV SETs 150, the memory cells 178, and the resistors 176.

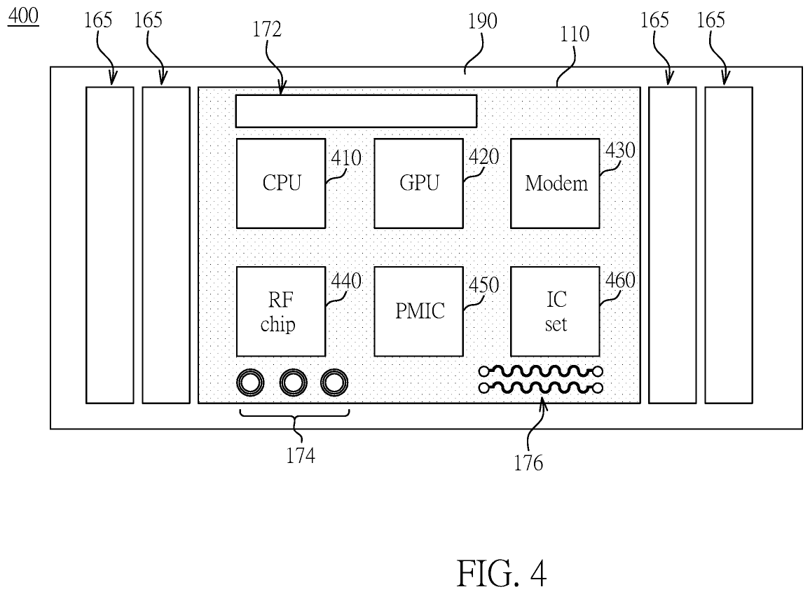

FIG. 4 shows a top view 400 of the semiconductor package 100 according to one example. Specifically, the top view 400 shows the interposer 110 (e.g., a silicon interposer), a CPU (central processing unit) 410, a GPU (graphics processing unit) 420, a Modem (modulation and demodulation processor) 430, an RF (Radio Frequency) chip 440, a PM IC (power management integrated circuit) 450, and an IC set 460 that includes any other suitable ICs to be put on the silicon interposer 110. These ICs on the interposer 110 shown in FIG. 4 can be made via different technology nodes, such as N16, N7, N5, N3, N2, or 0.18 micron. And all the above-mentioned elements shown in FIG. 4 are disposed above the substrate 190. One or more passive components 165, which may in include capacitors, inductors, and/or resistors may be located on or in the substrate 190. Any other devices that are suitable for use may also be put on or in the substrate 190.

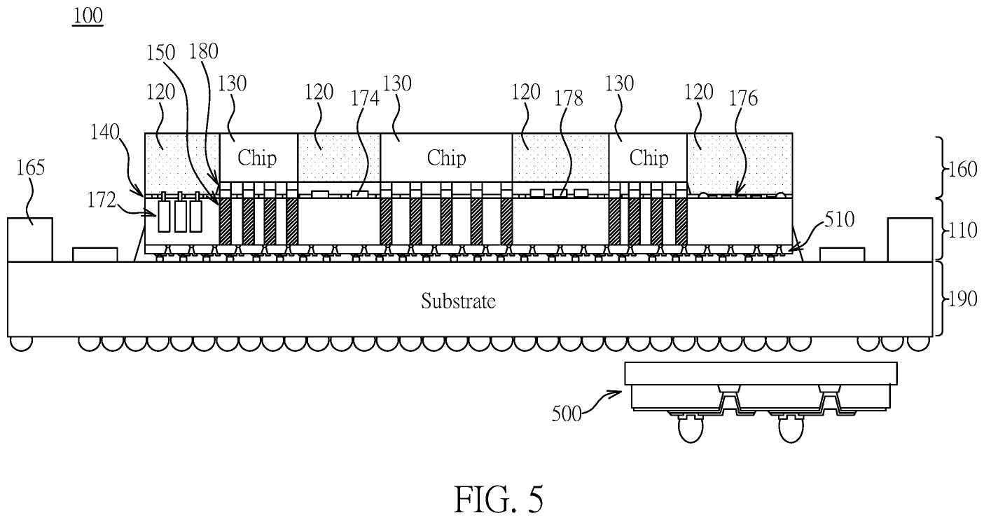

FIG. 5 shows the semiconductor package 100 according to one example. The connection between the interposer 110 and the substrate 190 can be made using flip chip bumps 500. There can be an RDL (redistribution layer) 510 disposed between the interposer 110 and solder bumps 195.

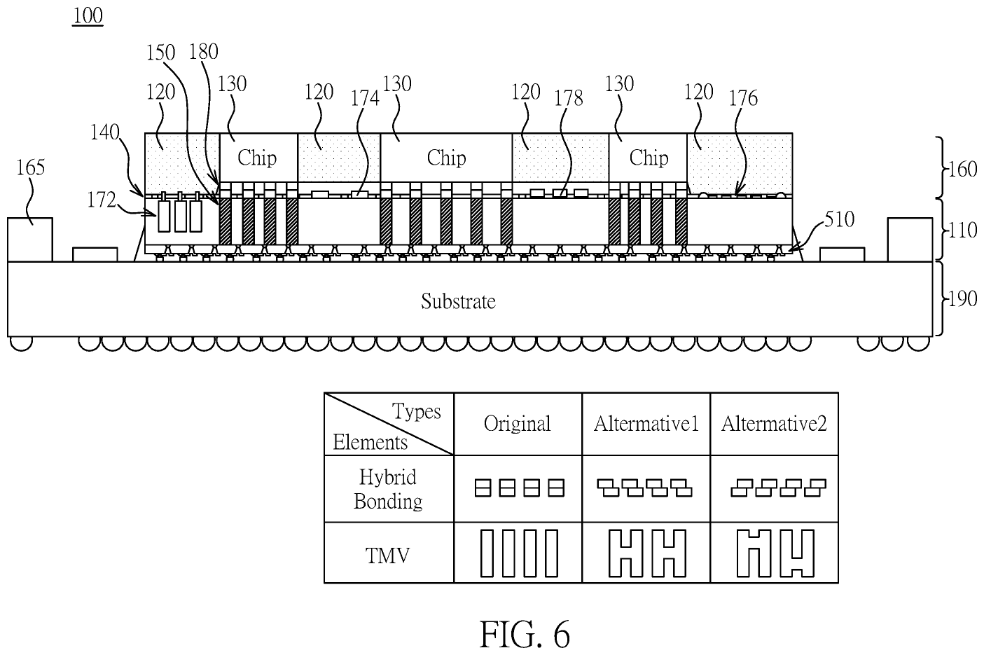

FIG. 6 shows the semiconductor package 100 according to one example. The interposer 110 may be implemented as a molded interposer whose base material is a molding material. In addition, with the aid of the molding material within the molded interposer 110, the semiconductor package 100 has lower cost. The molded interposer 110 may include the capacitors 172, the TMVs (through mold via) 150, and other chips. The chips 130 or components in or on the molded interposer 110 may be memory modules. Other components, such as inductors 174 or resistors 176 can be located on a surface of the molded interposer 110. There can be an RDL (redistribution layer) 140 located on the surface of the molded interposer 110. At least a part of an antenna structure can also be located in the RDL 140.

The semiconductor package 100 can have several types of hybrid bonding structures 180 between the chips 130 and the TMVs 150. In a first example, an original type of the hybrid bonding structure 180 includes connection components with bonding of two aligned metal pieces. In a second example, an alternative type of the hybrid bonding structure 180 includes connection components with bonding of two shifted metal pieces. The multiple metal pieces are slightly shifted but still have effective physical connection in between. The shifts may be implemented as a left-to-right tilt, i.e., as shown as Alternative 1 in FIG. 6, or may be implemented as a right-to-left tilt, i.e., as shown as Alternative 2 in FIG. 6. The semiconductor package 100 may also have several types of TMVs 150. For example, the semiconductor package may include one or more bridges that connect part or all of the TMV sets 150 in between and form an H-shaped connection. Different bridges can be at same or different levels, or a combination of same and different levels (i.e., partially the same and partially different). With the aid of the bridge among TMV sets, i.e., the H-shaped connection, the TMV sets lead to lower resistance in electronic transmission.

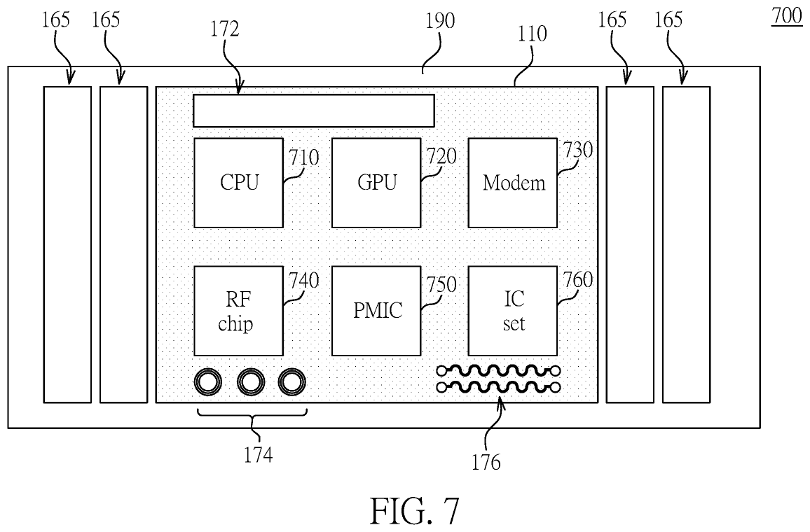

FIG. 7 shows a top view 700 of the semiconductor package 100. The top view 700 of the semiconductor package 100 illustrates the molded interposer 110, a CPU (central processing unit) 710, a GPU (graphics processing unit) 720, a Modem (modulation and demodulation processor) 730, an RF chip 740, a PM IC (power management IC) 750, and an IC set 760 that includes any suitable ICs to be put on the molded interposer 110. These suitable ICs can be made via several technology nodes, such as N16, N7, N5, N3, N2, or 0.18 micron. All the above-mentioned elements in FIG. 7 are disposed above the substrate 190. Passive components 165 may include capacitors, inductors, and/or resistors that are located on or in the substrate. Any other devices that are suitable for use can also be put on or in the substrate 190.

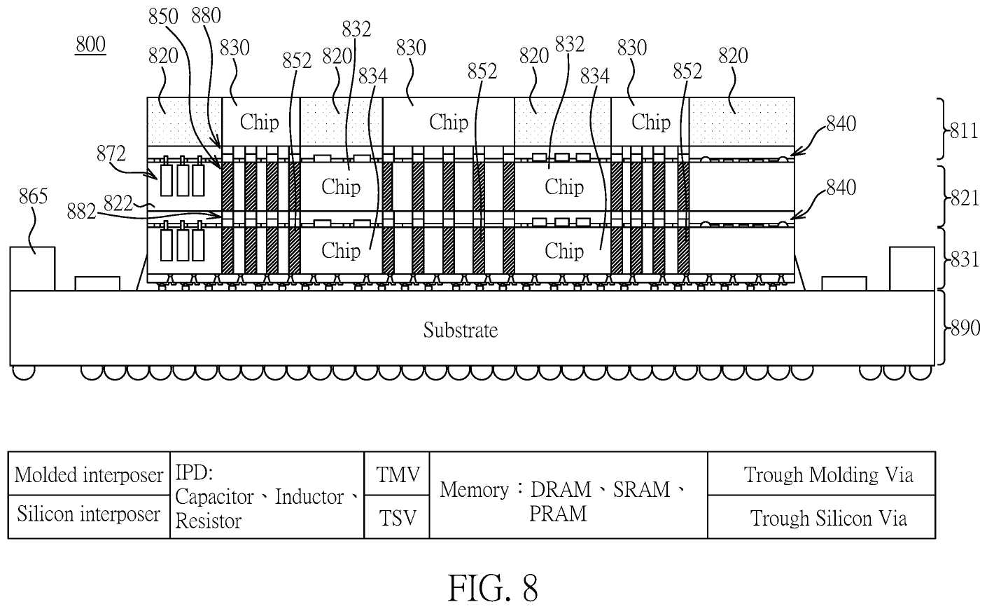

FIG. 8 shows the semiconductor package 800 according to a second embodiment of the present disclosure. The semiconductor package 110 has three layers 811, 821 and 831 and a substrate 890. The first layer (a top layer) 811 includes multiple chips 830. A molding material 820 is used to fill the space between the chips 830. The second layer (the middle layer) 821 includes multiple chips 832, TMVs (through mold vias) 850, and capacitors 872. A molding material 822 is also used in the second layer 821 to fill the space between the chips 832, the TMVs 850, and the capacitors 872. The third layer 831 includes multiple chips 834, or a single chip 834 with multiple devices formed on the single chip 834. The third layer 831 can be implemented using as a silicon layer. The third layer 831 can include TSV SETs (through silicon via) 852. The connection between the chips 830 in the first layer 811 and the TMVs 852 in the second layer 821 can be implemented using a hybrid bonding 880. The hybrid bonding 880 may bond two or more pieces of metal pillars. The connection between the TMVs 850 in the second layer 821 and the TSV SETs 852 in the third layer 831 can also be a hybrid bonding 882. The hybrid bonding 882 may bonding two or more pieces of metal pillars. One of the chips 832 in the second layer 821 can be implemented as a memory chip. The second layer 821 and the third layer 831 can respectively include RDLs (redistribution layer) 840 on their surfaces. The RDLs 840 on or in the second layer 821 and the third layer 831 can form part of an antenna structure. The third layer 831 is connected to the substrate 890 that may be implemented by a PCB (printed circuit board). The second layer 821 may also include passive components, which may include resistors, capacitors, and/or inductors. The third layer 831 may also include passive components, which may include resistors, capacitors, and/or inductors. In another example, the second layer 821 and the third layer 831 may exchange with each other. That is, the second layer 821 may be implemented as a silicon interposer, and the third layer 831 may be implemented as a molded interposer. By introducing more layers in the disclosed semiconductor package, functionality of the disclosed semiconductor package is correspondingly raised because more chips and/or passive components fit in.

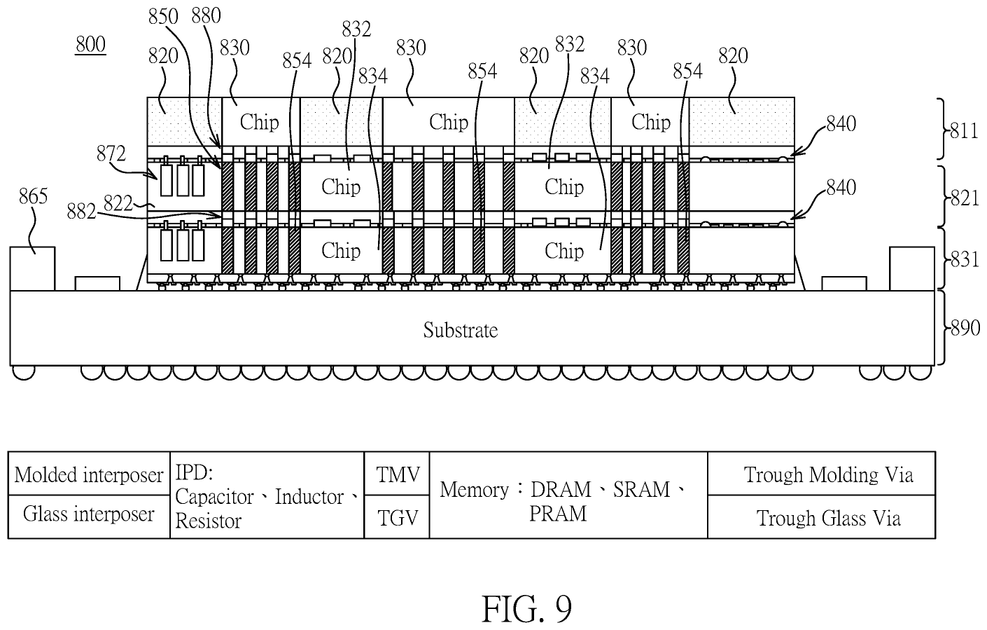

FIG. 9 shows the semiconductor package 800 according to one example. Slightly different from the semiconductor package 800 shown in FIG. 8, the third layer 831 may be alternatively implemented as a glass layer. And more specifically, the third layer 831 may include multiple TGVs (through glass via) 854. The connection between the TMVs 850 in the second layer 821 and the TGVs 854 in the third layer 831 can also be the hybrid bonding 882. In another example, the second layer 821 and the third layer 831 can exchange with each other. That is, the second layer 821 is implemented as a glass interposer and the third layer 831 is implemented as a molded interposer.

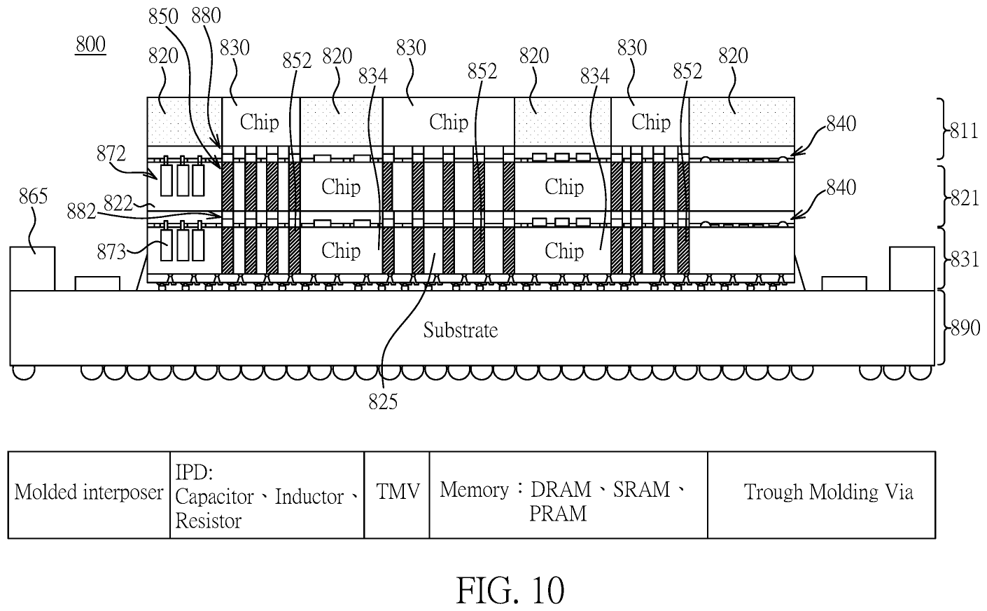

FIG. 10 shows the semiconductor package 800 according to one example. Slightly different from the semiconductor package 800 shown in FIG. 8, the third layer 831 includes multiple chips 834, TMVs (through mold vias) 852, and capacitors 873. A molding material 825 is also used in the third layer 831 to fill the space between the chips 834, the TMVs 852, and the capacitors 873.

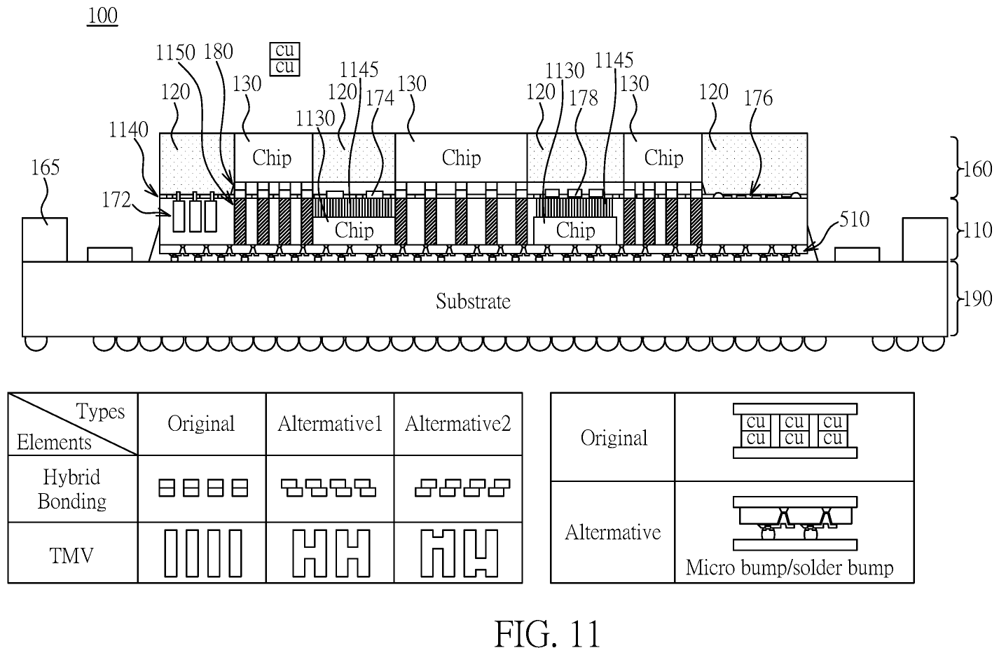

FIG. 11 shows the semiconductor package 100 according to one example that shares certain resemblance with FIG. 1. The first layer 160 (the top layer) is a molded interposer that includes multiple chips 130. The second layer 110 is also a molded interposer that includes capacitors 172, TMVs (through mold via) 1150, and multiple chips 1130. In one example, the chips 1130 or components in or on the molded interposer 160 may be memory cells. The second layer 110 may also include a corresponding multiple connection vias structures 1145 on top of the chips 1130 that are connected to the vias. In this way, the vias structures 1145 provide spacing between the chip 1130 and the surface of the second layer 110. Other components, such as inductors or resistors can be located on a surface of the molded interposer 110. There can be an RDL 1140 (redistribution layer) located on the surface of the second layer 110. At least a part of an antenna structure can be located in the RDL 140. The semiconductor package 100 can have several types of hybrid bonding structures 180 between the chips 1130 and the TMVs 1150. An original type of the hybrid bonding structure 180 includes connection components that bond two aligned metal pieces. An alternative type of the hybrid bonding structure 180 includes connection components that bond two or more shifted metal pieces, which are slightly shifted but still have effective physical connection. The shifts between metal pieces may be arranged in a left-to-right manner or in a right-to-left manner. In another example, a micro bump structure or a solder bump structure can applied to replace the hybrid bonding structure 180. In one example, the semiconductor package 100 can have several types of TMVs 1150 in connection manners. For example, as shown as the first type Alternative 1 and the second type Alternative 2 in FIG. 11, there can be one or more bridges connecting between two TMVs 1150 and form an “H” shape connection that apply different bridges at different levels.

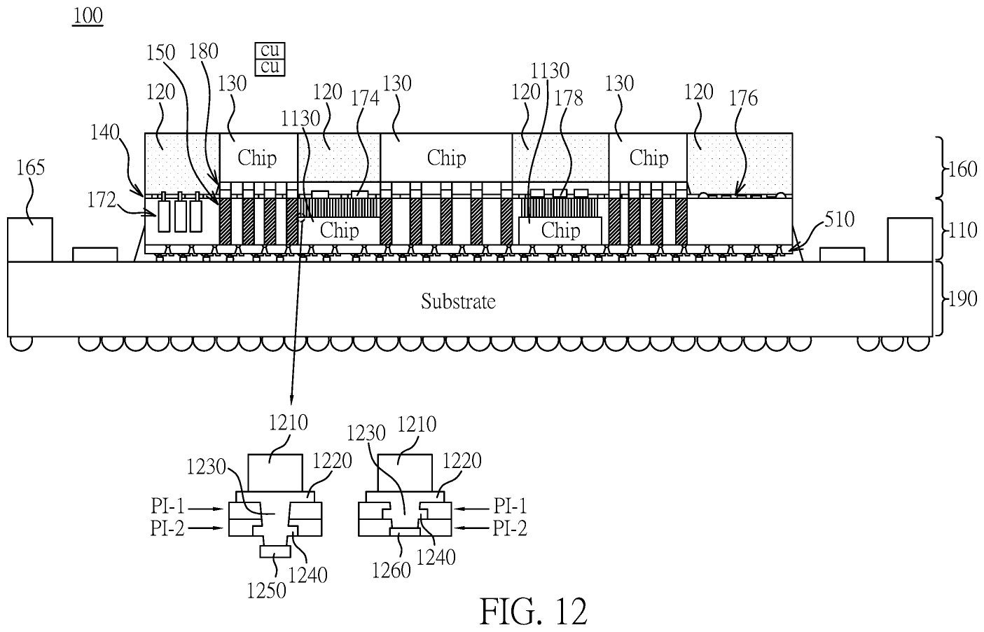

FIG. 12 shows the semiconductor package 100 according to one example that shares certain resemblance with FIG. 11. Specifically, the differences lie in detailed connections between the vias and the chip. In one example, a copper via 1210 or conductive via 1210 that is located on a metal pad 1220. The metal pad 1220 is located on a first polyimide layer (PI-1) that is in turn located on a second polyimide layer (PI-2). An extended via 1230 goes through the first polyimide layer PI-1 and the second polyimide layer PI-2. A first lateral pad 1240 is formed near a lower surface of the second polyimide layer PI-2. A second lateral pad 1250 is formed on an end of the extended via 1230. In this way, a fin-like structure is formed to balance the disclosed semiconductor package's vertical stress. In another example, the copper via 1210 is located on the metal pad 1220. The metal pad 1220 is located on the first polyimide layer (PI-1) that is in turn located on the second polyimide layer (PI-2). The extended via 1230 goes through the polyimide layers (PI-1) and (PI-2). The first lateral pad 1240 is instead located between the polyimide layers (PI-1) and (PI-2). The second lateral pad 1260 is formed near the lower surface of the second polyimide layer (PI-2). Similarly, a correspondingly formed fin-like structure aids in reducing a vertical stress of the extended via 1230.

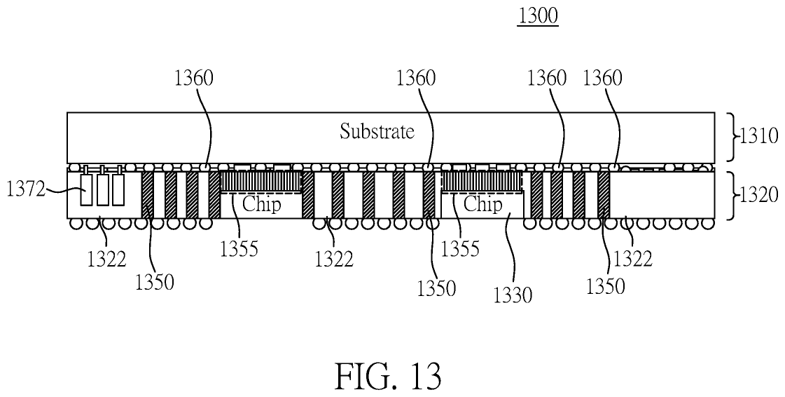

FIG. 13 shows a semiconductor package 1300 according to one example. The semiconductor package 1300 includes a first layer 1310 and a second layer 1320. The first layer (the top layer) 1310 is a substrate that may be implemented as a printed circuit board. The second layer 1320 is a molded interposer that includes multiple chips 1330, capacitors 1372, and TMVs (through mold vias) 1350. A molding material 1322 is used to fill the space between the chips 1330, the capacitors 1372, and/or the TMVs 1350. The second layer 1320 may include a via structure 1355 that includes multiple vias on top of the chips 1330 in one example. The via structure 1355 are connected to the chips 1330. In one example, the via structure 1355 can be implemented using copper vias. The first layer 1310 and the second layer 1320 may be connected through solder bumps 1360. In one example, an antenna can be embedded in the substrate 1310.

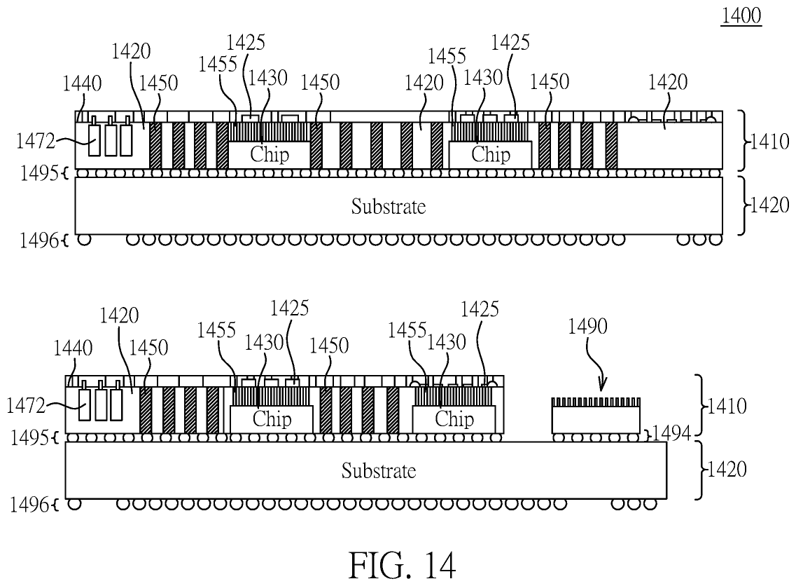

FIG. 14 shows a semiconductor package 1400 that includes a first layer 1410 and a second layer 1420 according to one example. The first layer (the top layer) 1410 is a molded layer. A portion of an antenna structure 1425 is located on top of the first layer 1410. In one example, the first layer 1410 includes capacitors 1472, TMVs (through mold vias) 1450, and multiple chips 1430. A molding material 1420 can be used to fill the space between the capacitors 1472, the TMVs 1450, or the chips 1430. The grounding of an antenna structure can be located in the chips 1430. An RDL 1440 can be formed at any suitable interfaces in the semiconductor package. For example, the upper surface of the molded layer 1410, the lower surface of the molded layer 1410, or the upper surface of the chips 1430. The RDL 1440 can also be used as a grounding layer for the antenna 1425. In another example, the grounding layer can be made using a metal layer in the main substrate. The semiconductor package 1400 may include a plurality of vias 1455 on top of the chips 1430. The vias 1455 provide proper spacing of the antenna structure 1425. The second layer 1420 is a substrate in one example. The substrate 1420 is connected to the first layer 1410 through solder bumps 1495. The substrate 1420 may in turn connect to other components through solder bumps 1496 on the other side. Optionally, a connector 1490 is connected to the substrate 1420 through solder bumps 1494. Also, in one example, the connector 1490 may in turn connect to another main board or another electronic system.

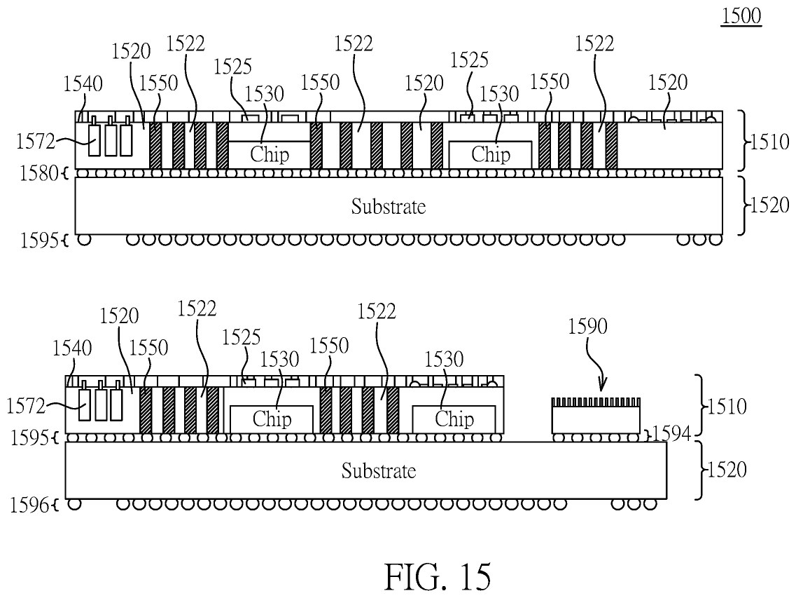

FIG. 15 shows a semiconductor package 1500 that includes a first layer 1510 and a second layer 1520 according to one example. The first layer (the top layer) 1510 is a molded layer. A portion of an antenna structure 1525 is located on top of the first layer 1510. The first layer 1510 includes capacitors 1572, TMVs (through mold vias) 1550, and multiple chips 1530. In one example, a molding material 1522 is used to fill the space between the capacitors 1572, the TMVs 1550, and/or the chips 1530. An RDL (redistribution layer) 1540 is formed on a surface of the first layer 1510. The grounding of the antenna structure 1525 can be located in the RDL 1540. The TMVs 1550 provide proper spacing of the antenna structure 1525. The second layer 1520 may be a substrate that is connected to the first layer 1510 through solder bumps 1580. The substrate 1520 can in turn connected to other components through solder bumps 1595 on the other side. A connector 1590 can be connected to the substrate 1520 through solder bumps 1594 and in turn connect to other main board or electronic system. The primary difference between FIG. 15 and FIG. 14 lies in the absence of the vias 1455 above the chips 1430.

### Multi-Band Molded Module

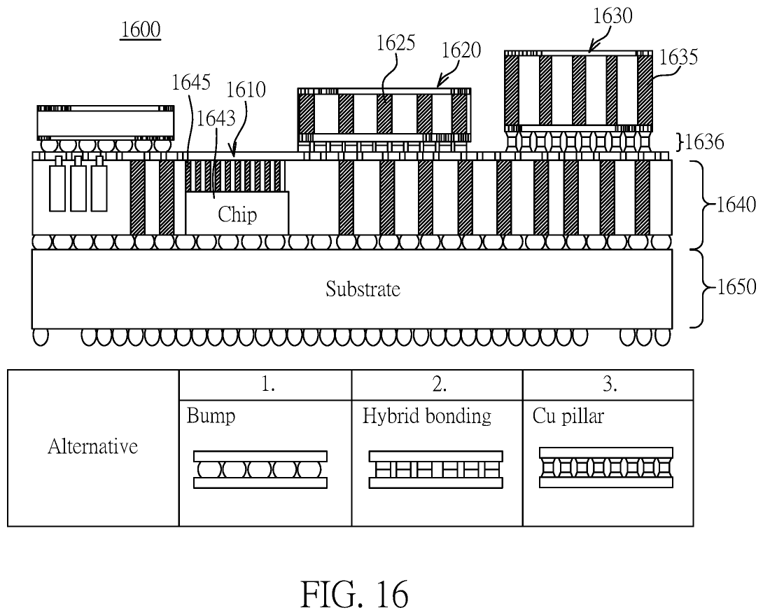

FIG. 16 shows a semiconductor package 1600 according to a third embodiment of the present disclosure. The semiconductor package 1600 includes multiple antenna modules, a molded interposer, and a main substrate. The multiple antenna modules include a high-band mmW (Millimeter-Wave) antenna module 1610, a mid-band mmW antenna module 1620, and a low-band mmW antenna module 1630.

In this example, the high-band mmW antenna module 1610 is attached on the surface of the molded interposer 1640. Multiple vias 1645 within the molded interposer 1640 are connected to the high-band mmW antenna 1610 and connected to a chip 1643 in the molded layer 1640. There are metal layers in the chip 1643 used as a grounding layer for the antenna module 1610. The vias 1645 can provide proper spacing for the high-band mmW antenna module 1610. In one example, at least part of an antenna is located at the top side of the multiple vias 1645 as a thin-film interface, that is, the part of the antenna is located at where the antenna module 1610's arrow points at. The antenna modules 1610, 1620 and 1630 can have more or less antennas depending on respective specification requirements. In one example, the mid-band mmW antenna 1620 module uses one molded layer and multiple TMVs 1625. The height of the TMVs 1625 can provide proper spacing for required wavelengths of the mid-band mmW antenna module 1620. A grounding portion of the mid-band mmW antenna module 1620 can be located on the lower surface of the molded layer or located in an additional RDL (redistribution layer) on the lower surface of the molded layer or located in an additional RDL on the upper surface of the molded interposer, or located in a chip inside. In one example, the low-band mmW module 1630 uses one molded layer and multiple TMVs 1635. The height of the TMVs 1635 can provide proper spacing for required wavelengths of the low-band mmW module 1630. Also, the low-band mmW module 1630's grounding portion can be located on the lower surface of the molded layer or located in an additional RDL (redistribution layer) on the lower surface of the molded layer or located in an additional RDL on the upper surface of the molded interposer, or located in a chip inside. In addition, in one example, the low-band mmW module 1630 is connected to the molded interposer 1640 via a plurality of solder bumps 1636.

The antenna modules 1610, 1620 and 1630 can have different heights for different required bandwidths and/or wavelengths. In this way, the antenna modules 1610, 1620 and 1630 can be designed to receive signals of various frequencies. In some examples, lengths of the antenna modules 1610, 1620 and 1630 are designed to be different fractions of a wavelength, e.g., one-half, one-fourth, one-eighth, and etc. In some examples, connection structures between the antenna modules 1610, 1620 and 1630 and the molded interposer 1640 can be solder bumps, hybrid bonding, or copper pillars.

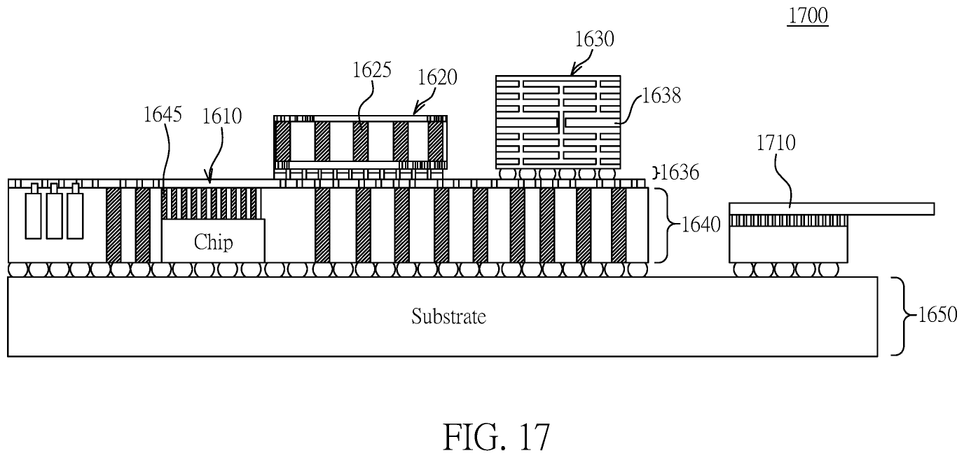

FIG. 17 shows a semiconductor package 1700 according to one example that shares certain resemblance with FIG. 16. The semiconductor package 1700 slightly differs from the semiconductor package 1600 in that the semiconductor package 1700 further includes a connector 1710 located on the main substrate 1650. The connector 1710 can be used to further connect to an external LCP (liquid crystal polymer) or MB (main board). The low-band mmW module 1630 is connected to a small substrate 1638.

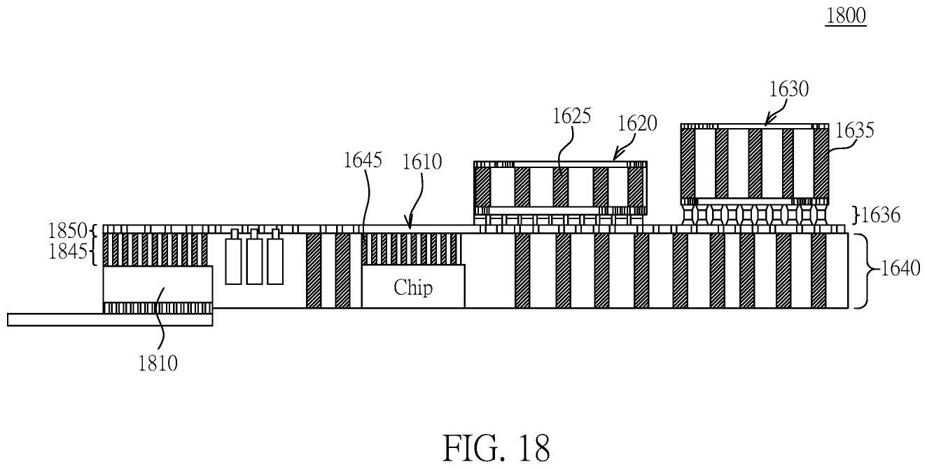

FIG. 18 shows a semiconductor package 1800 according to one example that shares certain resemblance with FIG. 16. The semiconductor package 1800 does not have the main substrate 1650 in comparison. A connector 1810 is directly connected to the molded interposer 1640. Multiple metal vias 1845 are located in the molded interposer 1640 and are connected to the connector 1810. The semiconductor package 1800 may include an RDL 1850 on the upper surface of the molded interposer 1640. The RDL 1850 can be used to connect to both the connector 1810 and other components on or in the molded interposer 1640.

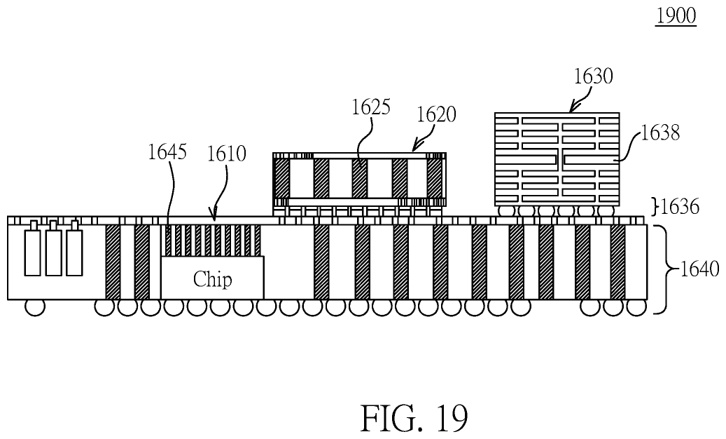

FIG. 19 shows a semiconductor package 1900 according to one example that shares certain resemblance with FIG. 16. The semiconductor package 1900 differs from the semiconductor package 1600 in that the low-band mmW antenna module 1630 uses a small substrate 1638. The antenna is located on top of the substrate. The substrate can be connected to the molded interposer 1640 through solder bumps.

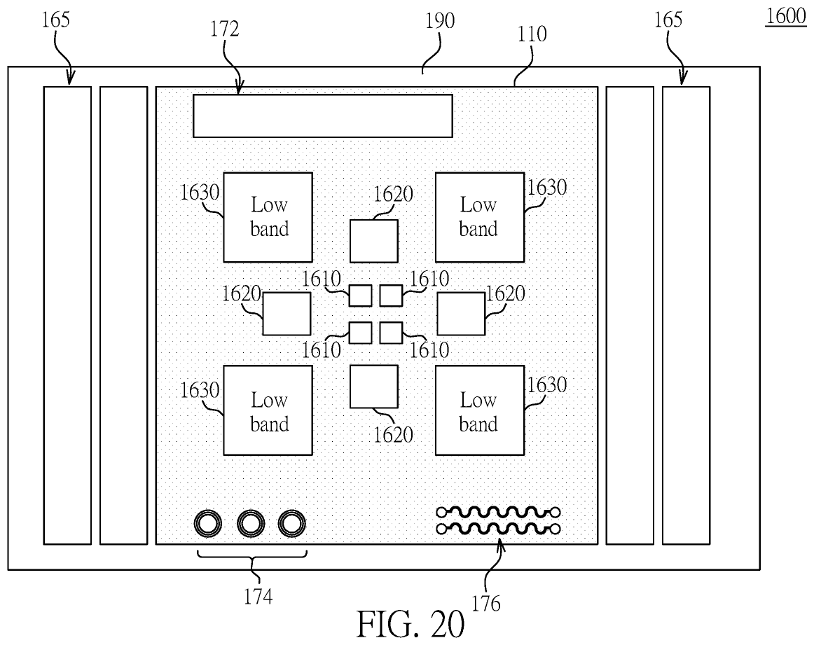

FIG. 20 shows a top view of the semiconductor package 1600 shown in FIG. 16 according to one example. The low-band mmW antenna modules 1630 have larger areas and are located on four quadrants from the top view. The mid-band mmW antenna modules 1620 have relatively smaller areas and are located between the low-band mmW antenna modules 1630. The high-band mmW antenna modules 1610 have even smaller areas and are located between the mid-band mmW antenna modules 1620.

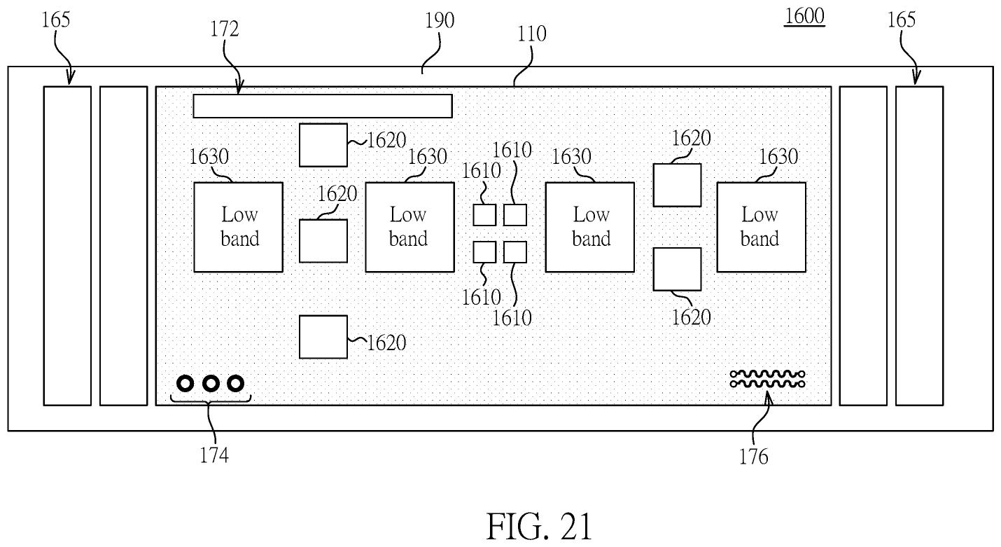

FIG. 21 shows a top view of a semiconductor package 1600 according to one example. The low-band mmW antenna modules 1630 have larger areas and are located on two sides from the top view. The mid-band mmW antenna modules 1620 have relatively smaller areas and are located in between the low-band mmW antenna modules 1630. The high-band mmW antenna modules 1610 have even smaller areas and are located near the central location and between the mid-band mmW antenna modules 1620 as well as the low-band mmW antenna modules 1630.

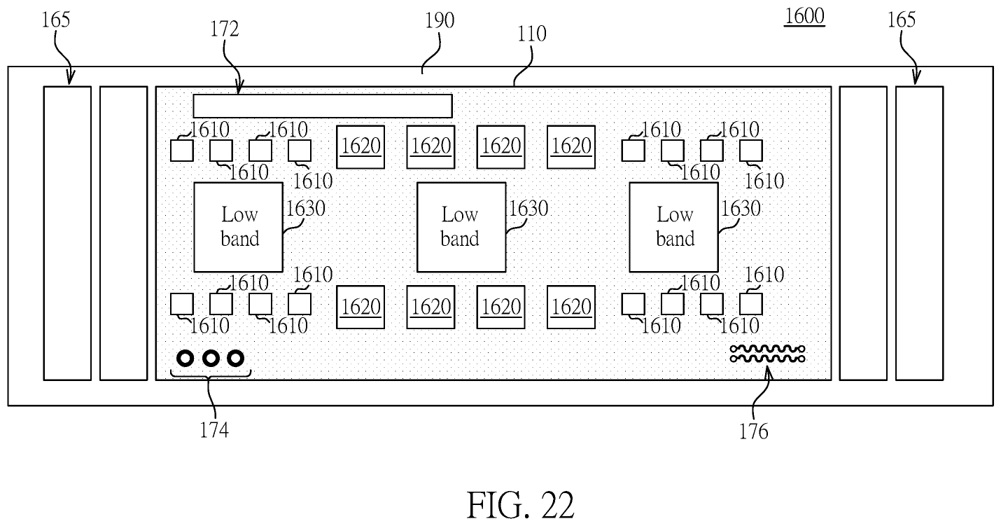

FIG. 22 shows a top view of the semiconductor package 1600 according to one example. The low-band mmW antenna modules 1630 have larger areas and are located around the central location from the top view. The mid-band mmW antenna modules 1620 have relatively smaller areas and are located on two sides of the low-band mmW antenna modules 1630. The high-band mmW antenna modules 1610 have even smaller areas and are located near the corners from the top view and with respect to the mid-band mmW antenna modules 1620 as well as the low-band mmW antenna modules 1630.

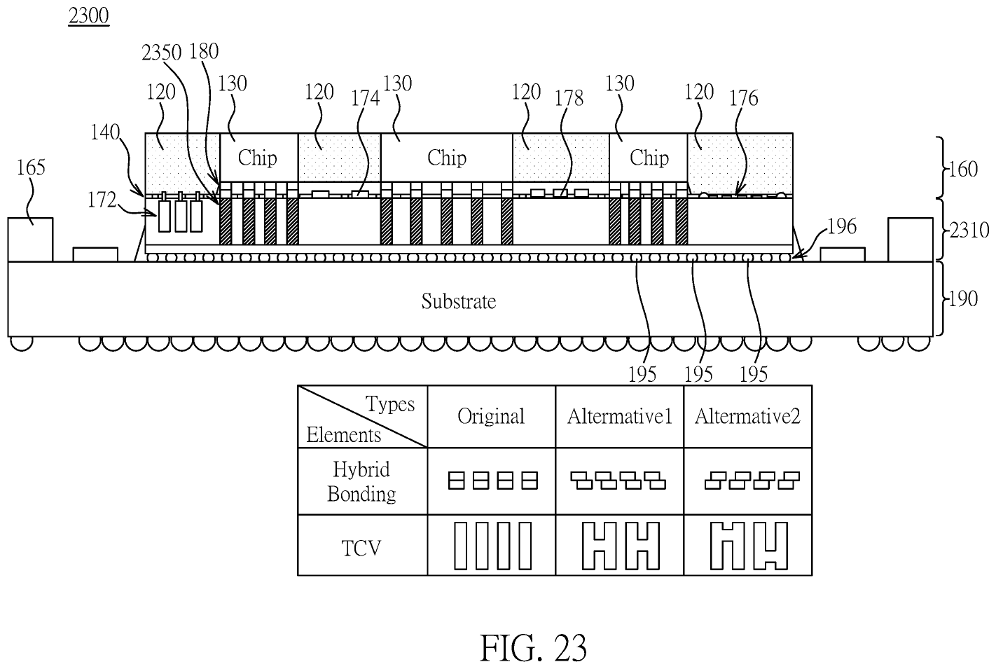

FIG. 23 shows a semiconductor package 2300 according to a fourth embodiment of the present disclosure. The semiconductor package 2300 is similar to the semiconductor package 1600 shown in FIG. 2, except for a difference that the semiconductor package 2300 uses a ceramic layer instead of the silicon layer used in FIG. 2 because it can provide better signal integrity. Therefore, the TSV SETs (through silicon via) 150 in FIG. 2 are replaced by TCVs (through ceramic via) 2350.

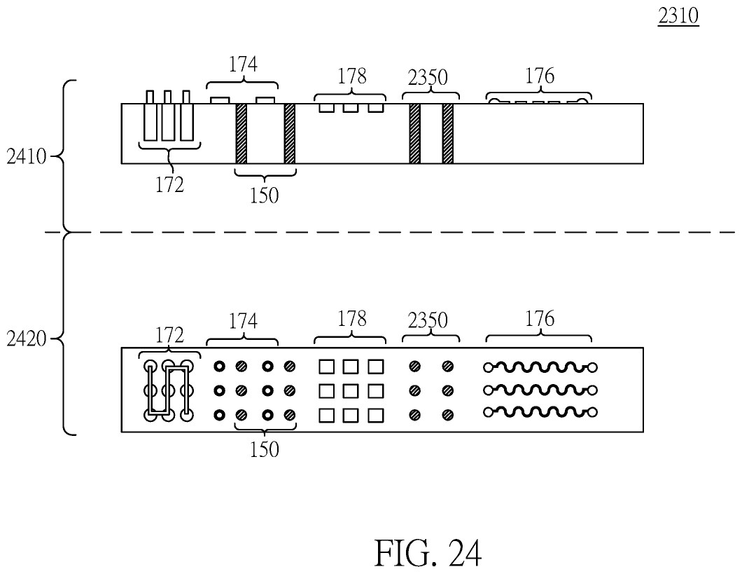

FIG. 24 shows a cross-sectional view 2410 and a top view 2420 of the interposer 2310 of the semiconductor package 2300. The interposer 2310 is similar with the interposer 110 shown in FIG. 3, except for the difference that the interposer 2310 uses a ceramic layer instead of a silicon layer. Therefore, the TSV SETs (through silicon via) 150 are replaced by TCVs (through ceramic via) 2350.

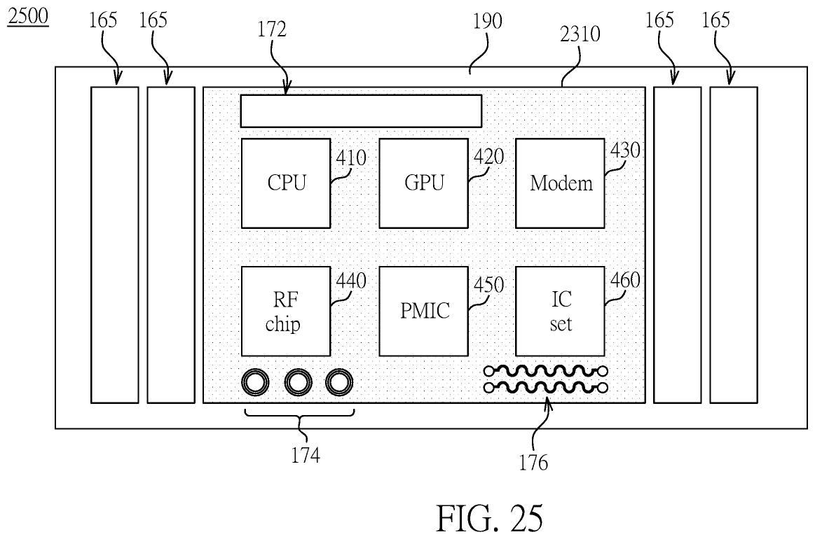

FIG. 25 shows a top view 2500 of the semiconductor package 2300 according to one example. The top view 2500 is similar to the top view 400 shown in FIG. 4, except for the difference in that the semiconductor package 2300 uses a ceramic layer to replace the silicon layer.

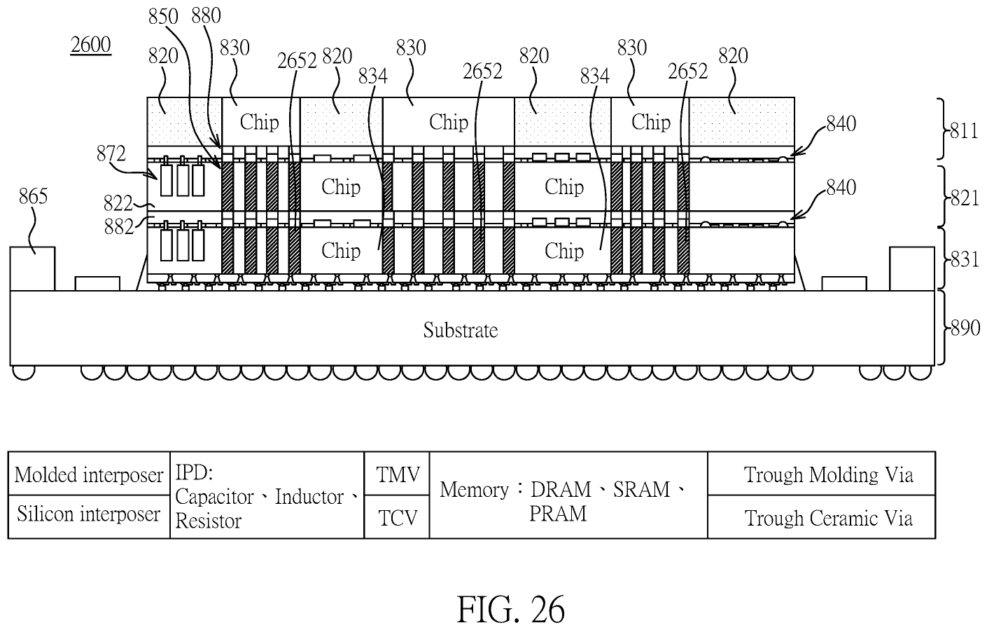

FIG. 26 shows a semiconductor package 2600 according to one example. The semiconductor package 2600 is similar with the semiconductor package 800 shown in FIG. 8, except for the difference in that semiconductor package 2600 uses a ceramic layer as the third layer to replace the silicon layer. Therefore, the TSV SETs (through silicon via) 852 are replaced by TCVs (through ceramic via) 2652.

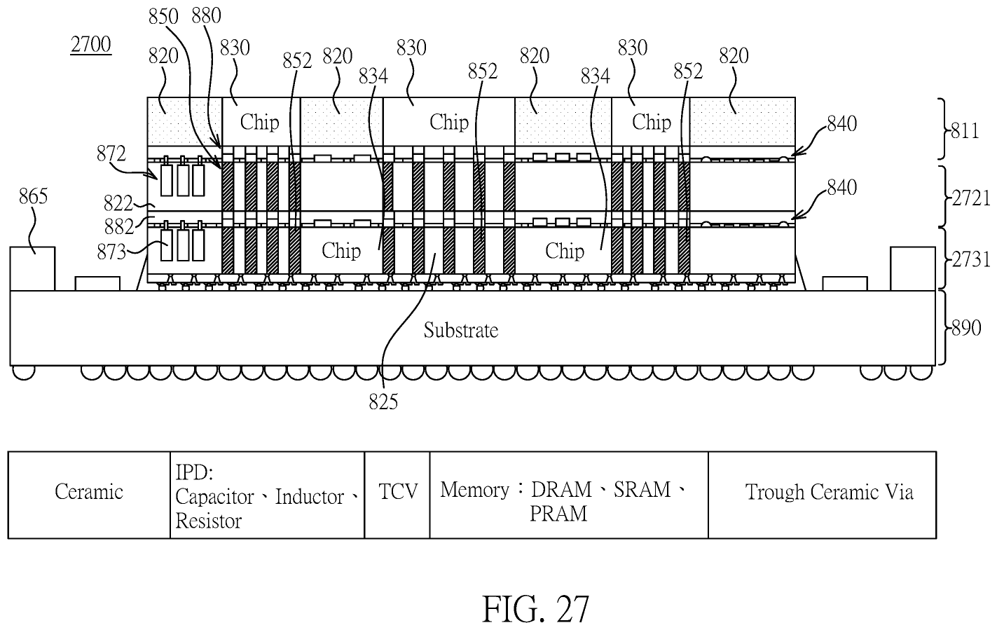

FIG. 27 shows a semiconductor package 2700 according to one example. The semiconductor package 2700 is similar to the semiconductor package 800 shown in FIG. 8, except for the difference in that the semiconductor package 2700 uses ceramic layers to replace the silicon layers in the second layer 2721 and the third layer 2731. Therefore, the TSV SETs (through silicon via) become TCV (through ceramic via).

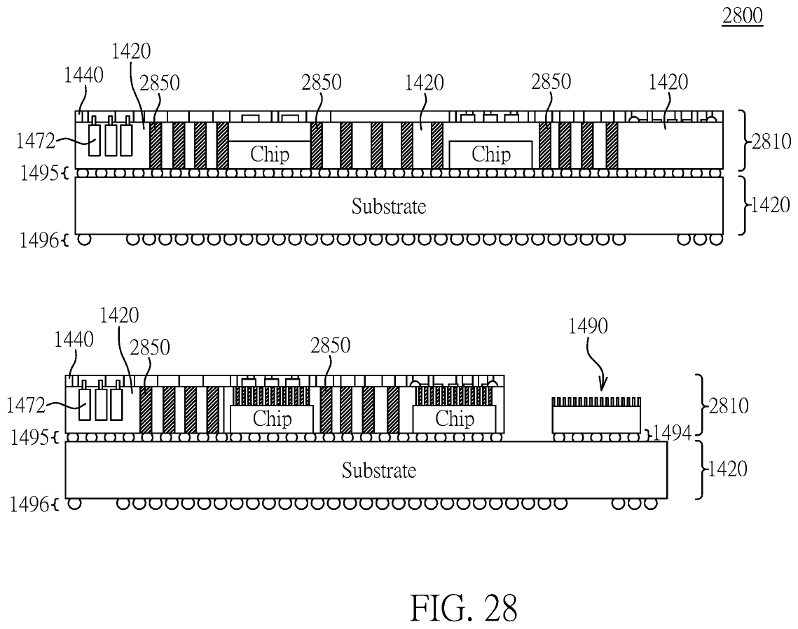

FIG. 28 shows a semiconductor package 2800 according to one example. The semiconductor package 2800 is similar with the semiconductor package 1400 shown in FIG. 14, except for the difference in that the semiconductor package 2800 uses ceramic layers to replace the silicon layer in the first layer 2810. Therefore, the TSV SETs 1450 (through silicon via) become TCVs (through ceramic via) 2850. The ceramic layer can further include capacitors, inductors, resistors, and/or memory cells such as DRAM, SRAM, or RRAM.

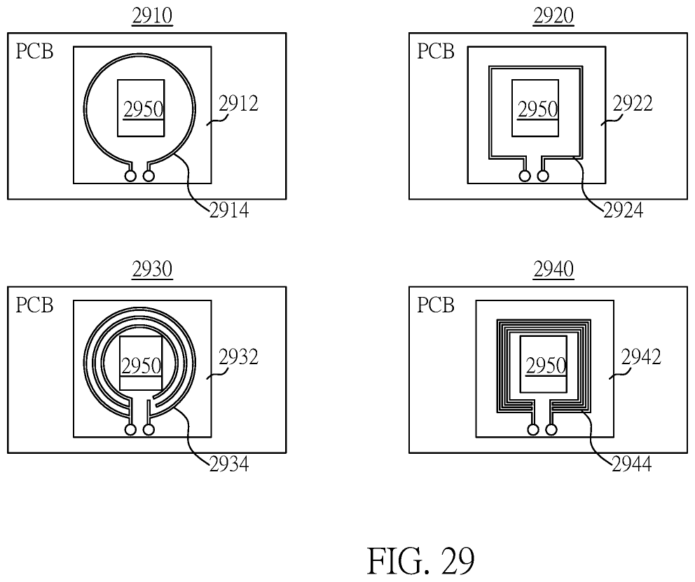

FIG. 29 shows top views of different types of antenna modules 2910, 2920, 2930 and 2940 that are optionally applied in the above-disclosed semiconductor packages according to some examples of the present disclosure. Each the antenna modules 2910, 2920, 2930 and 2940 may respectively include an absorber 2912, 2922, 2932 and 2942 and a loop antenna 2914, 2924, 2934 and 2944 in turn. The loop antennas may be in circle-shaped (i.e., loop antennas 2914 and 2934), rectangular-shaped (i.e., loop antennas 2924 and 2944), or any other suitable shapes. The loop antenna may have single turn (i.e., loop antennas 2914 and 2924) or multiple turns (i.e., loop antennas 2934 and 2944). From the top views, the absorbers 2912, 2922, 2932 and 2942 cover the loop antennas 2914, 2924, 2934 and 2944 respectively and in turn. The absorbers 2912, 2922, 2932 and 2942 are used to absorb spurious signals or unwanted harmonics of a signal. There can be a noise source 2950 at the center of the loop antennas 2914, 2924, 2934 and 2944 from the top view. In some examples, the abovementioned absorbers absorb noises via the metal-shielding effect.

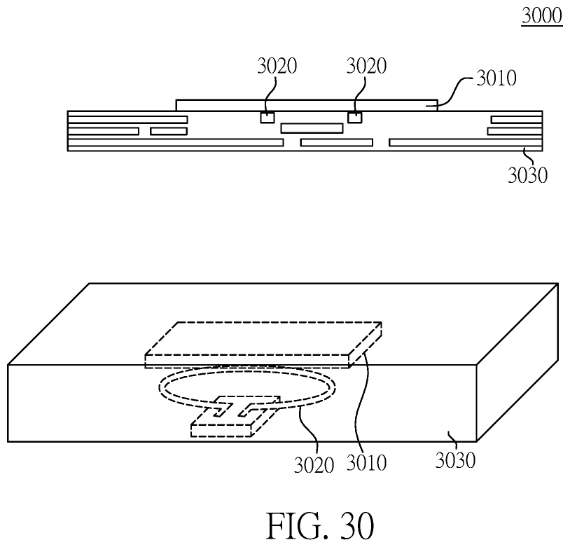

FIG. 30 shows a cross-sectional view of an antenna module 3000 that is optionally applied in the above-disclosed semiconductor packages according to some examples of the present disclosure. The antenna module 3000 can be formed in or integrated with a PCB (printed circuit board) or a substrate 3030. From the cross-sectional view, an absorber 3010 is on top of the PCB or substrate 3030. The loop antenna 3020 is located beneath the absorber 3010. The loop antenna 3020 can be located within the PCB or substrate 3030. There may be a noise source 3040 under the loop antenna 3030 to be neutralized.

Those skilled in the art will readily observe that numerous modifications and alterations of the device and method may be made while teachings of the invention. Accordingly, the above disclosure should be construed as limited only by the metes and bounds of the appended claims.

What is claimed is:

1. A semiconductor package, comprising:
a substrate;
an interposer, disposed above the substrate, the interposer comprises a plurality of through silicon vias (TSV) sets;
a primary component layer, disposed above the interposer, the primary component layer comprises a plurality of first chips and a first molding material utilized for filling the space between the plurality of first chips;
a first redistribution layer, disposed between the primary component layer and the interposer, the first redistribution layer comprises at least one portion of an antenna structure;
a plurality of solder bumps, disposed between the substrate and the interposer; and
a first hybrid bonding structure, disposed between the plurality of first chips and the plurality of TSV sets for electrical connection in between, the first hybrid bonding structure comprises a plurality of connection components that respectively apply bonding of a plurality of metal pieces in between.

2. The semiconductor package of claim 1, wherein each of the plurality of connection components applies bonding of a plurality of aligned metal pieces in between.

3. The semiconductor package of claim 1, wherein each of the plurality of connection components applies bonding of a plurality of shifted metal pieces in between.

4. The semiconductor package of claim 1, further comprising:
a second redistribution layer, disposed between the interposer and the plurality of solder bumps.

5. The semiconductor package of claim 1, further comprising:
a flip chip bump, formed as a connection between the interposer and the substrate.

6. The semiconductor package of claim 1, wherein the interposer further comprises at least one second chip that is disposed between two of the plurality of TSV sets.

7. The semiconductor package of claim 1, wherein the interposer is silicon-based.

8. The semiconductor package of claim 1, wherein the interposer further comprises at least one passive component, and wherein the first molding material is further utilized for filling the space between the plurality of first chips and the at least one passive component.

9. The semiconductor package of claim 1, further comprising:
an under-fill material, configured to fill space between the plurality of the solder bumps.

10. The semiconductor package of claim 1, wherein the substrate comprises at least one passive component.

11. The semiconductor package of claim 1, wherein each of the plurality of connection components comprises a plurality of copper pillars.

12. The semiconductor package of claim 1, further comprising at least one bridge to part or all of the plurality of TSV sets.

13. The semiconductor package of claim 12, wherein the at least one bridge has same or different levels, or a combination of same and different levels.

14. The semiconductor package of claim 1, further comprising:
a supplemental layer, comprising:
a plurality of third chips; and
a second molding material, utilized for filling the space between the plurality of third chips; and
a second hybrid bonding structure, utilized for establishing connection between the plurality of first chips and the plurality of third chips, the second hybrid bonding structure comprises a plurality of connection components that respectively apply bonding of a plurality of metal pieces in between.

15. The semiconductor package of claim 14, wherein the supplemental layer further comprises a plurality of through glass vias (TGV) sets, in two of which at least one of the plurality of third chips are disposed.

16. The semiconductor package of claim 14, wherein the supplemental layer further comprises a plurality of through mold vias (TMV) sets, in two of which at least one of the plurality of third chips are disposed.

17. The semiconductor package of claim 14, wherein the supplemental layer further comprises at least one passive component, and wherein the second molding material is further utilized for filling the space between the plurality of third chips and the at least one passive component.

18. The semiconductor package of claim 1, wherein the primary component layer further comprising a plurality of connection via structures that are respectively disposed on top of the plurality of first chips and are connected to the plurality of first chips.

19. The semiconductor package of claim 18, wherein each of the plurality of connection via structures comprises:
a copper via;
a metal pad, disposed below the copper via;
a first polyimide layer, disposed below the metal pad;
a second polyimide layer, disposed below the first polyimide layer;
an extended via, configured to go through the first polyimide layer and the second polyimide layer;
a first lateral pad, formed near a lower surface of the second polyimide layer; and
a second lateral pad, formed on an end of the extended via.

20. The semiconductor package of claim 18, wherein each of the plurality of connection via structures comprises:
a copper via;
a metal pad, disposed below the copper via;
a first polyimide layer, disposed below the metal pad;
a second polyimide layer, disposed below the first polyimide layer;
an extended via, configured to go through the first polyimide layer and the second polyimide layer;
a first lateral pad, disposed between the first polyimide layer and the second polyimide layer; and
a second lateral pad, formed near the lower surface of the second polyimide layer.

21. The semiconductor package of claim 1, wherein the interposer is ceramic-based.

22. A semiconductor package, comprising:
a molded layer, on top of which a portion of an antenna structure is disposed, the molded layer comprises a plurality of chips and a molding material that is configured to fill the gap between the plurality of chips;
a first redistribution layer, disposed neighboring to the molded layer, and configured to be a grounding layer for the antenna structure;
a substrate; and
a plurality of solder bumps, disposed between the substrate and the interposer, and the substrate is configured to connect to the molded layer through the plurality of solder bumps.

23. The semiconductor package of claim 22, further comprising:
a connector, connected to the substrate through the plurality of solder bumps.

24. The semiconductor package of claim 22, further comprising:
a plurality of vias, disposed on top of the plurality of chips, and configured to provide spacing of the antenna structure.

25. The semiconductor package of claim 22, wherein the plurality of vias comprises copper vias.

26. The semiconductor package of claim 22, wherein the molded layer further comprises at least one passive element and a plurality of through mold vias (TMV);
Wherein the molding material is further configured to fill the gap between the plurality of chips, the at least one passive element and the plurality of TMVs.
